(19) United States
(12) Patent Application Publication
(10) Pub. No.: US 2026/0171294 A1
(43) Pub. Date: Jun. 18, 2026

(54) WIDEBAND INDUCTIVE COMPONENT

(71) Applicant: QUALCOMM Incorporated, San Diego, CA (US)

(72) Inventors: Gajanan Maroti DEVPUJE, Bangalore (IN); Ayush MITTAL, Bangalore (IN); Sreenivasa MALLIA, Bangalore (IN); Arvind KEERTI, San Ramon, CA (US); Yido KOO, Belmont, CA (US); Anurag TIWARI, Bangalore (IN); Krishnaswamy THIAGARAJAN, Bangalore (IN); Osama ELHADIDY, San Diego, CA (US); Bhushan Shanti ASURI, San Diego, CA (US)

(21) Appl. No.: 18/982,754

(22) Filed: Dec. 16, 2024

(51) Int. Cl. H01F 27/28; H03H 7/42; H04B 1/40

(52) U.S. Cl. CPC H01F 27/28; H03H 7/42; H04B 1/40

(57) ABSTRACT

Certain aspects of the present disclosure provide wideband inductive component(s). An example method of wireless communication by an apparatus includes feeding a first signal to a wideband inductive component configured to operate at a first frequency band in a first mode. The method further includes feeding a second signal to the wideband inductive component configured to operate at a second frequency band in a second mode.

### INTRODUCTION

### Field of the Disclosure

Aspects of the present disclosure relate to wireless communications, and more particularly, to wideband inductive components.

### Description of Related Art

Wireless communications systems are widely deployed to provide various telecommunication services such as telephony, video, data, messaging, broadcasts, etc. These wireless communications systems may employ multiple-access technologies capable of supporting communications with multiple users by sharing available wireless communications system resources with those users. Wireless communication devices may communicate radio frequency (RF) signals via any of various suitable radio access technologies (RATs) including, but not limited to, 5G New Radio (NR), Evolved Universal Terrestrial Radio Access (E-UTRA), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., Institute of Electrical and Electronics Engineers (IEEE) 802.11 specifications), any future RAT, and/or the like.

In certain cases, a wireless communications device is equipped with a RF transceiver (also referred to as an RF front-end) for communicating RF signals. In general, a baseband signal is modulated to convey information using a modulation technique, such as phase-shift keying (PSK) or any other suitable modulation technique. In a transmit mode, the RF transceiver is responsible for multiplexing the baseband signal with an RF carrier signal that is transmitted over the air (e.g., a wireless communication channel). Such an operation is called upconversion. In a receive mode, the RF transceiver converts a received RF signal to the baseband signal. Such an operation is called downconversion. The received baseband signal then can be demodulated into the information encoded at a transmitter. The RF transceiver may include a cascade of components in a transmit chain and a receive chain, respectively. The cascade of components may include, for example, one or more of attenuators, switches, couplers, filters, mixers, amplifiers, frequency synthesizers, oscillators, antenna tuners, duplexers, diplexers, detectors, etc.

Although there have been great technological advancements in RF circuitry over many years, challenges still exist. For example, RF circuitry (such as inductive components) can still encounter internal capacitances, interactions between active and inactive segments, or the like. Accordingly, there is a continuous desire to improve the technical performance of RF circuitry, such as inductive components.

### SUMMARY

Some aspects provide a radio frequency (RF) transceiver. The RF transceiver includes a planar transformer comprising a first conductive winding and a second conductive winding. The first conductive winding comprises a first set of conductive spirals and a second set of conductive spirals selectively coupled to the first set of conductive spirals, wherein the first set of conductive spirals forms a first area inside the first set of conductive spirals, wherein the second set of conductive spirals forms a second area inside the second set of conductive spirals, wherein the first area is non-overlapping in space with the second area, wherein the first set of conductive spirals comprises at least one first conductive segment arranged in a layer, and wherein the second set of conductive spirals comprises at least one second conductive segment arranged in the layer. The second conductive winding is configured to be inductively coupled to at least a portion of the first conductive winding, wherein the second conductive winding comprises a third set of conductive spirals having at least one third conductive segment being arranged adjacent to the at least one first conductive segment in the layer.

Some aspects provide a radio frequency (RF) transceiver. The RF transceiver includes a balun comprising a first conductive winding, a second conductive winding, and a third conductive winding. The first conductive winding comprises a first set of conductive spirals and a second set of conductive spirals selectively coupled to the first set of conductive spirals. The second conductive winding is selectively coupled to a reference node, wherein the second conductive winding is configured to be inductively coupled to at least a first portion of the first conductive winding. The third conductive winding is selectively coupled to the reference node, wherein the third conductive winding is configured to be inductively coupled to at least the first portion of the first conductive winding.

Some aspects provide a method of wireless communication by an apparatus. The method includes feeding a first signal to a wideband inductive component configured to operate at a first frequency band in a first mode. The method further includes feeding a second signal to the wideband inductive component configured to operate at a second frequency band in a second mode.

Other aspects provide: an apparatus operable, configured, or otherwise adapted to perform any one or more of the aforementioned methods and/or those described elsewhere herein; a non-transitory, computer-readable medium comprising instructions that, when executed by a processor of an apparatus, cause the apparatus to perform the aforementioned methods as well as those described elsewhere herein; a computer program product embodied on a computer-readable storage medium comprising code for performing the aforementioned methods as well as those described elsewhere herein; and/or an apparatus comprising means for performing the aforementioned methods as well as those described elsewhere herein. By way of example, an apparatus may comprise a processing system, a device with a processing system, or processing systems cooperating over one or more networks.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the drawings. It is to be noted, however, that the appended drawings illustrate only certain typical aspects of this disclosure and are therefore not to be considered limiting of its scope, for the description may admit to other equally effective aspects.

FIG. 1 depicts an example wireless communications system.

FIG. 2 depicts an example wireless communications device communicating with another device.

FIG. 3 depicts an example transmit chain that includes one or more wideband inductive components.

FIG. 4A depicts an example wideband radio frequency (RF) transformer.

FIGS. 4B and 4C depict cross-sectional views of the RF transformer of FIG. 4A.

FIG. 5 depicts an example schematic of the RF transformer of FIG. 4A.

FIG. 6A depicts an example state of the RF transformer of FIG. 4A.

FIG. 6B depicts another example state of the RF transformer of FIG. 4A.

FIG. 7 depicts another example wideband RF transformer.

FIG. 8 depicts an example schematic of the RF transformer of FIG. 7.

FIG. 9A depicts an example state of the RF transformer of FIG. 7.

FIG. 9B depicts an example state of the RF transformer of FIG. 7.

FIG. 10 depicts an example schematic of a wideband inductive component with certain secondary winding isolation features.

FIG. 11 depicts an example method for wireless communications by an apparatus.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

Aspects of the present disclosure provide apparatus, methods, processing systems, and computer-readable mediums for wideband inductive component(s).

Certain radio frequency (RF) transceivers (such as a wireless local area network (WLAN) transceiver and/or a wireless wide area network (WWAN) transceiver) may employ band-specific inductive elements in transmit chains and/or receive chains to support communications across multiple frequency bands (such as the 2.4 GHz frequency bands and 5 GHz frequency bands). The transceiver may employ inductive components to form filters or tuning components. As an example, a filter having one or more inductive components may be coupled to the output of upconversion mixer(s) to reject certain harmonic distortion(s) that may form in a RF signal output by the upconversion mixers. The inductive components may include, for example, inductors, transformers, or baluns. In certain cases, to enable wide bandwidth performance, the transceiver may have an inductive component tuned to a specific frequency band for each of the frequency bands. As an example, the harmonic rejection filter may have an inductor tuned to a low band corresponding to 2.4 GHz bands and another inductor tuned to a high band corresponding to 5 GHz bands.

Technical problems for inductive components include, for example, effective usage of chip area, effective mitigation of internal capacitances, and/or effective mitigation of interaction between active and inactive inductive segments for wideband inductive component architectures. In certain cases, a wideband inductive component (such as a planar transformer) may be formed with a primary winding formed within the area of a secondary winding. Such a structure may use a non-trivial amount of area of chip space to form the windings of the transformer. To adjust the inductance of the primary winding, a switch may be coupled between segments of the primary winding in order to selectively bypass certain portions of the primary winding, and a similar switch arrangement may be used to adjust the inductance of the secondary winding. However, due to the inactive segments of the windings being arranged adjacent to the active segments of the windings (for example, when the switches are closed), the inactive segments may interact with active segments of the windings, for example, resulting in internal capacitances and/or mutual inductances that affect the performance of the transformer.

In certain cases, the secondary winding of a balun may be coupled to multiple switched output ports that selectively feed particular antennas, which may be tuned to certain frequency bands. The switches of the output ports may have internal capacitances that affect the performance of the balun.

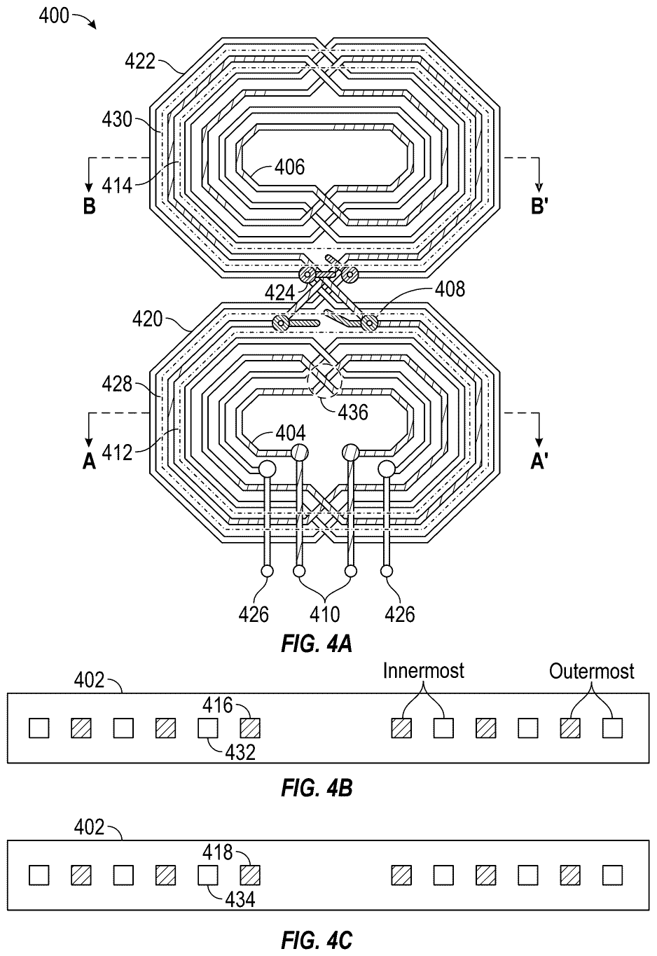

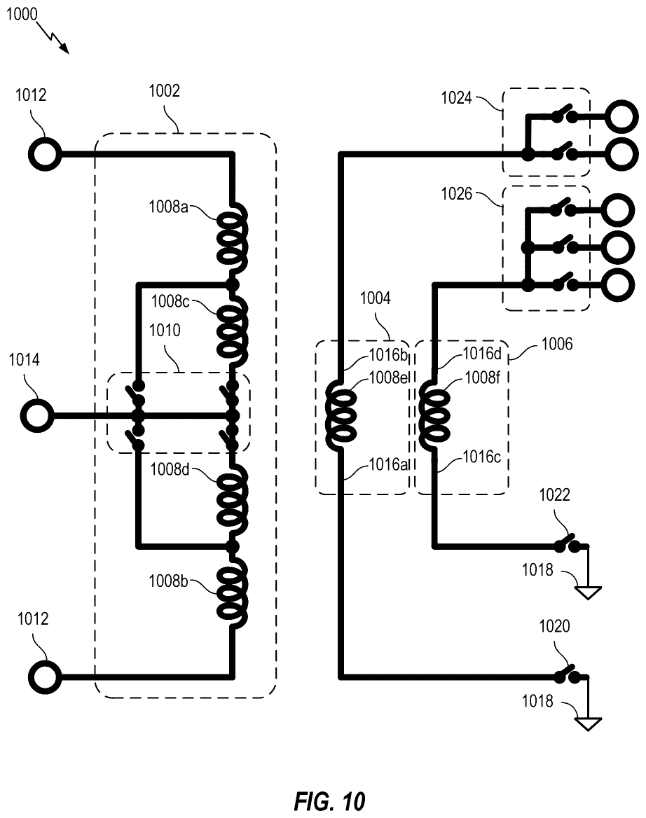

Certain aspects described herein may overcome the aforementioned technical problem(s), for example, by providing a wideband inductive component architecture that may enable reduced chip area, reduced interaction between inactive and active segments, and/or reduced internal capacitances. In certain aspects, the wideband inductive component architecture may include a transformer and/or a balun. The wideband inductive component may be formed using separate conductive spirals arranged in non-overlapping areas (hereinafter “non-overlapping spirals”) to reduce the interaction between active and inactive segments of the inductive component, for example, as further described herein with respect to FIGS. 4-9. In certain aspects, a switch may be coupled between a secondary winding and a reference node (e.g., a reference ground node) in order to selectively isolate the secondary winding from an active segment, for example, as further described herein with respect to FIG. 10. In certain aspects, the switched outputs of the secondary windings may be divided among the secondary windings depending on the operating frequency bands, for example, as further described herein with respect to FIG. 10.

Certain wideband inductive component(s) described herein may provide various beneficial technical effects and/or advantages. The wideband inductive component(s) may enable reduced chip area of the inductive component, reduced interaction between inactive and active segments of transformer or balun windings, and/or reduced internal capacitances. In certain aspects, the non-overlapping spirals may be formed in a compact area to use a reduced chip area for the inductive component. The non-overlapping spirals may reduce interaction between inactive and active segments of transformer windings and/or isolate active segments from the inactive segments. The isolation may enable reliable performance of the wideband inductive component(s), for example, in terms of reduced internal capacitances and/or a relatively high quality factor (e.g., 4.5 or more or 4.5-6.5) over a wide bandwidth of carrier frequencies (e.g., 2.4 GHz bands and 5 GHz-7.2 GHz).

In certain aspects, the switched reference nodes of the wideband inductive components may enable isolation between inactive and active segments of transformer or balun windings. In certain aspects, the divided switched outputs may reduce internal capacitances encountered at the secondary windings.

### Example Wireless Communications System

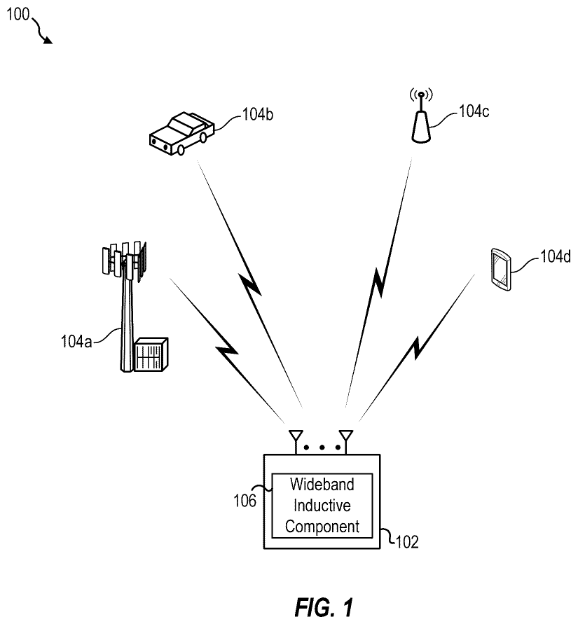

FIG. 1 illustrates an example wireless communications system 100 in which aspects of the present disclosure may be performed. For example, the wireless communications system 100 may include a wireless wide area network (WWAN) and/or a wireless local area network (WLAN). A WWAN may include a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation (2G) or Third Generation (3G) network), a code division multiple access (CDMA) system (e.g., a 2G/3G network), any future WWAN system, or any combination thereof. A WLAN may include a wireless network configured for communications according to an Institute of Electrical and Electronics Engineers (IEEE) standard such as one or more of the 802.11 standards, etc. In some cases, the wireless communications system 100 may include a device-to-device (D2D) communications network or a short-range communications system, such as Bluetooth communications or near field communications (NFC).

As illustrated in FIG. 1, the wireless communications system 100 may include a first wireless device 102 communicating with any of various second wireless devices 104a-d (hereinafter “the second wireless device 104”) via any of various radio access technologies (RATs), where a wireless device may refer to a wireless communications device. The RATs may include, for example, WWAN communications (e.g., E-UTRA and/or 5G NR), WLAN communications (e.g., IEEE 802.11), vehicle-to-everything (V2X) communications, non-terrestrial network (NTN) communications, short-range communications (e.g., Bluetooth), D2D communications, etc.

The first wireless device 102 may include any of various wireless communications devices including a user equipment (UE), a base station, a wireless station, an access point, customer-premises equipment (CPE), etc. In certain aspects, the first wireless device 102 includes a wideband inductive component 106 that enables reduced interaction between active and inactive segments of the inductive component (among other benefits), in accordance with aspects of the present disclosure.

The second wireless device 104 may include, for example, a base station 104a, a vehicle 104b, an access point (AP) 104c, and/or a UE 104d. Further, the wireless communications systems 100 may include terrestrial aspects, such as ground-based network entities (e.g., the base station 104a and/or access point 104c), and/or non-terrestrial aspects, such as a spaceborne platform and/or an aerial platform, which may include network entities on-board (e.g., one or more base stations) capable of communicating with other network elements (e.g., terrestrial base stations) and/or user equipment.

The base station 104a may generally include: a NodeB, enhanced NodeB (eNB), next generation enhanced NodeB (ng-eNB), next generation NodeB (gNB or gNodeB), access point, base transceiver station, radio base station, radio transceiver, transceiver function, transmission reception point, and/or others. The base station 104a may provide communications coverage for a respective geographic coverage area, which may sometimes be referred to as a cell, and which may overlap in some cases (e.g., a small cell may have a coverage area that overlaps the coverage area of a macro cell). A base station may, for example, provide communications coverage for a macro cell (covering relatively large geographic area), a pico cell (covering relatively smaller geographic area, such as a sports stadium), a femto cell (relatively smaller geographic area (e.g., a home)), and/or other types of cells.

The first wireless device 102 and/or the UE 104d may generally include: a cellular phone, smart phone, session initiation protocol (SIP) phone, laptop, personal digital assistant (PDA), satellite radio, global positioning system, multimedia device, video device, digital audio player, camera, game console, tablet, smart device, wearable device, vehicle, electric meter, gas pump, large or small kitchen appliance, healthcare device, implant, sensor/actuator, display, internet of things (IoT) devices, always on (AON) devices, edge processing devices, or other similar devices. A UE may also be referred to more generally as a mobile device, a wireless device, a wireless communications device, a wireless station (STA), a mobile station, a subscriber station, a mobile subscriber station, a mobile unit, a subscriber unit, a wireless unit, a remote unit, a remote device, an access terminal, a mobile terminal, a wireless terminal, a remote terminal, a handset, and other terms.

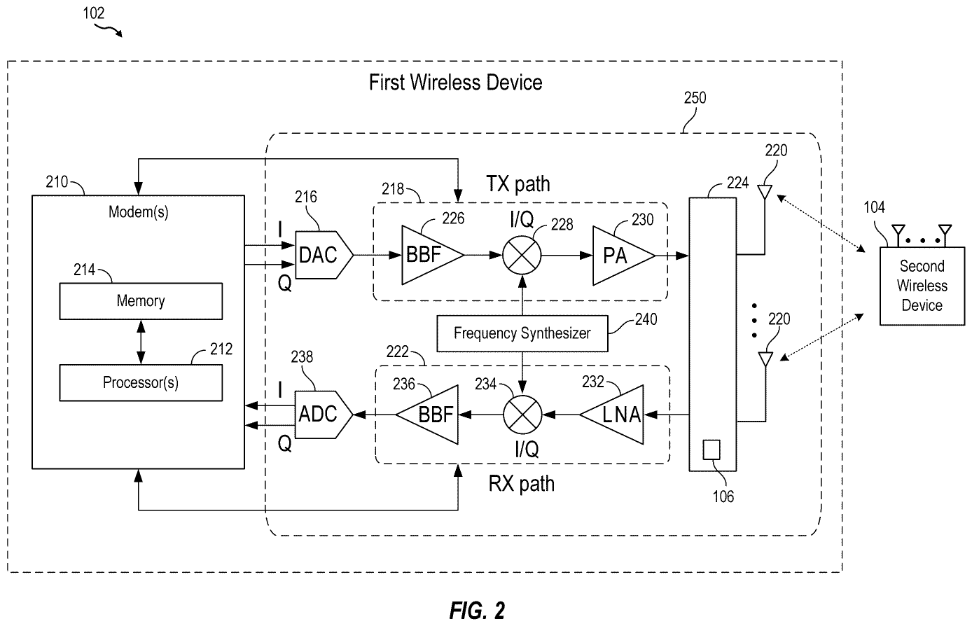

FIG. 2 illustrates example components of the first wireless device 102, which may be used to communicate with any of the second wireless devices 104.

The first wireless device 102 may be, or may include, a chip, system on chip (SoC), system in package (SiP), chipset, package, device that includes one or more modems 210 (hereinafter “the modem 210”). In some cases, the modem 210 may include, for example, any of a WWAN modem (e.g., a modem configured to communicate via E-UTRA 5G NR, and/or any future WWAN communications standards), a WLAN modem (e.g., a modem configured to communicate via IEEE 802.11 standards), a Bluetooth modem, a NTN modem, etc. In certain aspects, the first wireless device 102 also includes one or more RF transceivers (hereinafter “the RF transceiver 250”). In some cases, the RF transceiver 250 may be referred to as an RF front end (RFFE). In some aspects, the modem 210 further includes one or more processors, processing blocks or processing elements (hereinafter “the processor 212”) and one or more memory blocks or elements (hereinafter “the memory 214”). In certain aspects, the processor 212 and/or the memory 214 are implemented external or otherwise separate from the modem 210.

In certain aspects, the processor 212 may process any of certain protocol stack layers associated with a radio access technology (RAT). For example, the processor 212 may process any of an application layer, packet layer, WLAN protocol stack layers (e.g., a link or a medium access control (MAC) layer), and/or WWAN protocol stack layers (e.g., a radio resource control (RRC) layer, a packet data convergence protocol (PDCP) layer, a radio link control (RLC) layer, and a MAC layer).

The modem 210 may generally be configured to implement a physical (PHY) layer. For example, the modem 210 may be configured to modulate packets and to output the modulated packets to the RF transceiver 250 for transmission over a wireless medium. The modem 210 is similarly configured to obtain modulated packets received by the RF transceiver 250 and to demodulate the packets to provide demodulated packets. In addition to a modulator and a demodulator, the modem 210 may further include digital signal processing (DSP) circuitry, automatic gain control (AGC), a coder, a decoder, a multiplexer, and/or a demultiplexer (not shown).

As an example, while in a transmission mode, the modem 210 may obtain data from a data source, such as an application processor. The data may be provided to a coder, which encodes the data to provide encoded bits. The encoded bits may be mapped to points in a modulation constellation (e.g., using a selected modulation and coding scheme) to provide modulated symbols. The modulated symbols may be mapped, for example, to spatial stream(s) or space-time streams. The modulated symbols may be multiplexed, transformed via an inverse fast Fourier transform (IFFT) block, and subsequently provided to DSP circuitry for transmit windowing and filtering. The digital signals may be provided to a digital-to-analog converter (DAC) 216. In certain aspects involving beamforming, the modulated symbols in the respective spatial streams may be precoded via a steering matrix prior to provision to the IFFT block.

The modem 210 may be coupled to the RF transceiver 250 by a transmit (TX) path 218 (also known as a transmit chain) for transmitting signals via one or more antennas 220 (hereinafter “the antennas 220”) and a receive (RX) path 222 (also known as a receive chain) for receiving signals via the antennas 220. When the TX path 218 and the RX path 222 share the antennas 220, the paths may be coupled to the antennas 220 via an interface 224, which may include any of various suitable RF devices, such as a balun, a transformer, an antenna tuner, a switch, a duplexer, a diplexer, a multiplexer, and or like. As an example, the modem 210 may output digital in-phase (I) and/or quadrature (Q) baseband signals representative of the respective symbols to the DAC 216. In some examples, all or most of the elements illustrated as being included in the RF transceiver 250 are implemented in a single chip or die. For example, in some configurations, all of the elements of the RF transceiver except the antennas 220 are implemented on a single chip. In some other configurations, the interface 224 or a portion thereof is also omitted from the single chip.

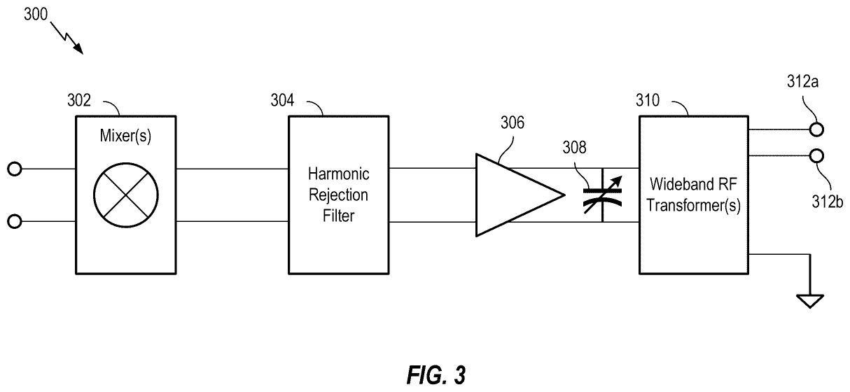

In certain aspects, the interface 224 may include the wideband inductive component 106 of FIG. 1. The wideband inductive component may enable reduced chip area of the inductive component, reduced interaction between inactive and active segments of transformer or balun windings, and/or reduced internal capacitances across a wideband of carrier frequencies, for example, 2.4 GHz to 7.2 GHz. Note the arrangement of the wideband inductive component 106 as a component of the interface 224 is an example to facilitate an understanding of the wideband inductive component 106 in an RF transceiver. Aspects of the present disclosure may be applied to other circuit architectures that include the wideband inductive component 106, for example, as further described herein with respect to FIG. 3.

Receiving I or Q baseband analog signals from the DAC 216, the TX path 218 may include a baseband filter (BBF) 226, a mixer 228 (which may include one or several mixers), and a power amplifier (PA) 230. The BBF 226 filters the baseband signals received from the DAC 216, and the mixer 228 mixes the filtered baseband signals with a transmit local oscillator (LO) signal to convert the baseband signal to a different frequency (e.g., upconvert from a baseband frequency to a radio frequency). In some aspects, the frequency conversion process produces the sum and difference frequencies between the LO frequency and the frequencies of the baseband signal. The sum and difference frequencies are referred to as the beat frequencies. Some beat frequencies are in the RF range, such that the signals output by the mixer 228 are typically RF signals, which may be amplified by the PA 230 before transmission by the antennas 220. The antennas 220 may emit RF signals, which may be received at the second wireless device 104. While one mixer 228 is illustrated, several mixers may be used to upconvert the filtered baseband signals to one or more intermediate frequencies and to thereafter upconvert the intermediate frequency signals to a frequency for transmission.

The RX path 222 may include a low noise amplifier (LNA) 232, a mixer 234 (which may include one or several mixers), and a baseband filter (BBF) 236. RF signals received via the antennas 220 (e.g., from the second wireless device 104) may be amplified by the LNA 232, and the mixer 234 mixes the amplified RF signals with a receive local oscillator (LO) signal to convert the RF signal to a baseband frequency (e.g., downconvert the RF signal to the baseband frequency). The baseband signals output by the mixer 234 may be filtered by the BBF 236 before being converted by an analog-to-digital converter (ADC) 238 to digital I or Q signals for digital signal processing. The modem 210 may receive the digital I or Q signals and further process the digital signals, for example, demodulating the digital signals into information.

Certain transceivers may employ frequency synthesizers with a voltage-controlled oscillator (VCO) to generate a stable, tunable LO frequency with a particular tuning range. Thus, the transmit LO frequency may be produced by a frequency synthesizer 240, which may be buffered or amplified by an amplifier (not shown) before being mixed with the baseband signals in the mixer 228. Similarly, the receive LO frequency may be produced by the frequency synthesizer 240, which may be buffered or amplified by an amplifier (not shown) before being mixed with the RF signals in the mixer 234. Separate frequency synthesizers may be used for the TX path 218 and the RX path 222.

While in a reception mode, the modem 210 may obtain digitally converted signals via the ADC 238 and RX path 222. As an example, in the modem 210, digital signals may be provided to the DSP circuitry, which is configured to acquire a received signal, for example, by detecting the presence of the signal and estimating the initial timing and frequency offsets. The DSP circuitry is further configured to digitally condition the digital signals, for example, using channel (narrowband) filtering, analog impairment conditioning (such as correcting for I/Q imbalance), and applying digital gain to ultimately obtain a narrowband signal. The output of the DSP circuitry may be fed to the AGC, which is configured to use information extracted from the digital signals, for example, in one or more received training fields, to determine an appropriate gain. The output of the DSP circuitry also may be coupled with the demodulator, which is configured to extract modulated symbols from the signal and, for example, compute the logarithm likelihood ratios (LLRs) for each bit position of each subcarrier in each spatial stream. The demodulator may be coupled with the decoder, which may be configured to process the LLRs to provide decoded bits. The decoded bits from all of the spatial streams may be fed to the demultiplexer for demultiplexing. The demultiplexed bits may be descrambled and provided to a medium access control layer (e.g., the processor 212) for processing, evaluation, or interpretation.

The modem 210 and/or processor 212 may control the transmission of signals via the TX path 218 and/or reception of signals via the RX path 222. In some aspects, the modem 210 and/or processor 212 may be configured to perform various operations, such as those associated with any of the methods described herein. The modem 210 and/or processor 212 may include a microcontroller, a microprocessor, an application processor, a baseband processor, a MAC processor, an artificial intelligence (AI) processor, a digital signal processor (DSP), an application specific integrated circuit (ASIC), a field programmable gate array (FPGA) or other programmable logic device (PLD), discrete gate or transistor logic, discrete hardware components, or any combination thereof. The memory 214 may store data and program codes (e.g., processor-readable instructions) for performing wireless communications as described herein. In some cases, the memory 214 may be external to the modem 210 and/or processor 212 and/or incorporated therein (as illustrated with the memory 214 or being incorporated with the processor 212).

FIG. 2 shows an example transceiver design. It will be appreciated that other transceiver designs or architectures may be applied in connection with aspects of the present disclosure. For example, while examples discussed herein utilize I and Q signals (e.g., quadrature modulation), those of skill in the art will understand that components of the transceiver may be configured to utilize any other suitable modulation, such as polar modulation. As another example, circuit blocks may be arranged differently from the configuration shown in FIG. 2, and/or other circuit blocks not shown in FIG. 2 may be implemented in addition to or instead of the blocks depicted.

### Example Wideband Inductive Component

Aspects of the present disclosure provide certain wideband inductive components that may enable reduced chip area, reduced interaction between inactive and active segments, and/or reduced internal capacitances, across a wide range of frequencies, for example, 2.4 GHz to 7.2 GHz and/or 1.7 GHz to 7.2 GHz.

FIG. 3 depicts an example transmit chain 300 that includes one or more wideband inductive components. The transmit chain 300 may be an example of a portion of the transmit path 218 of FIG. 2. In this example, the transmit chain 300 may include one or more mixers (hereinafter “the mixer 302”), a harmonic rejection filter 304, one or more amplifiers (hereinafter “the amplifier 306”), a capacitor bank 308, and one or more wideband RF transformer(s) (hereinafter “the RF transformer 310”). The mixer 302 may be an example of the mixer 228. The mixer 302 may convert a baseband signal to an RF signal and feed the RF signal to the harmonic rejection filter 304. The harmonic rejection filter 304 may be tuned to reject certain harmonic(s) that form in the output signal of the mixer 302. In certain cases, the harmonic rejection filter 304 may include a wideband inductive component, for example, as further described herein with respect to FIGS. 4A-10. The wideband inductive component may be an example of the wideband inductive component 106 of FIGS. 1 and 2.

The wideband inductive component may enable the harmonic rejection filter 304 to reject the harmonic(s) over a range of carrier frequencies associated with the RF signal. As an example, the harmonic rejection filter 304 may support harmonic rejection at a range of carrier frequencies including 2.4 GHz bands and 5 GHz to 7.2 GHz and/or 2.4 GHz to 7.2 GHz.

The amplifier 306 may be or include a power amplifier, such as the PA 230 of FIG. 2. In certain cases, the amplifier 306 may be or include a driver amplifier that drives the RF signal to a subsequent stage of amplification, for example, due to a power amplifier (such as the PA 230) being arranged in or on a different chip or circuit than a chip or circuit that includes the transmit chain 300. The amplifier 306 may obtain the filtered RF signal and feed an amplified RF signal to the capacitor bank 308 and the RF transformer 310. The RF transformer 310 may include a wideband inductive component, for example, as further described herein with respect to FIGS. 4A-10.

The capacitor bank 308 and the RF transformer 310 may form a bandpass filter. The bandpass filter may allow the RF signal to pass, and the bandpass filter may reject frequencies outside the carrier frequency of the RF signal. The RF transformer 310 may enable the bandpass filter to form one or more pass bands across a range of carrier frequencies, for example, including 2.4 GHz to 7.2 GHz. The RF transformer 310 may allow the amplifier 306 to operate across a wideband frequency range (e.g., the range of carrier frequencies associated with the RF transformer) without separate amplifiers tuned to specific frequency bands. Such a wideband amplifier may enable improved power consumption and/or chip area usage.

In certain cases, the RF transformer 310 may serve or operate as a balun to interface the differential outputs of the amplifier 306 and the unbalanced (or singled ended) line that feeds an output stage of the transmit chain 300, for example, including a power amplifier coupled to an antenna. The RF transformer 310 may include a plurality of outputs 312a, 312b to enable operation across a wide frequency band. As an example, the first output 312a may be coupled to a first antenna (such as one of the antennas 220) tuned to a first frequency band, and the second output 312b may be coupled to a second antenna (such as another one of the antennas 220) tuned to a second frequency band.

Note that the transmit chain 300 is an example circuit architecture that may include one or more wideband inductive components, such as a transformer or balun. Other suitable circuits may employ or include one or more wideband inductive components as described herein, including, for example, an impedance matching network, jammer rejection filter, receive chain, and/or the like.

### Example Wideband Inductive Component With a Switched Secondary Winding

FIG. 4A depicts an example wideband RF transformer 400 (hereinafter “the RF transformer 400”), and FIGS. 4B and 4C depict cross-sectional views of the RF transformer 400 taken across lines A-A′ and B-B′ of FIG. 4A, respectively. In certain aspects, the RF transformer 400 may be an example of a balun. The RF transformer 400 may be included in an RF transceiver, such as the RF transceiver 250 of FIG. 2 and/or a transmit chain, such as the transmit chain 300 of FIG. 3. The RF transformer 400 may be an example of the wideband inductive component 106 of FIGS. 1 and 2, and in certain cases, the RF transformer 400 may be an example of the wideband RF transformer 310 of FIG. 3.

In this example, the RF transformer 400 may be or include a planar transformer formed at, in, or on a layer 402 (e.g., a metal layer) of an integrated circuit, chip, package, or the like. The RF transformer 400 may include a first conductive winding (hereinafter “the first winding”) that includes a first set of conductive spirals 404 and a second set of conductive spirals 406. The first winding may be a primary winding of the RF transformer 400. The second set of conductive spirals 406 may be selectively coupled to the first set of conductive spirals 404 via a first switch 408. The first switch 408 may be coupled between the first set of conductive spirals 404 and the second set of conductive spirals 406. For example, the first switch 408 may be coupled between outer (e.g., outermost) conductive segments of the first set of conductive spirals 404 and outer (e.g., outermost) conductive segments of the second set of conductive spirals 406. The first switch 406 may have a first terminal coupled to a first outer conductive segment of the first set of conductive spirals 404 and a first outer conductive segment of the second set of conductive spirals 406, and the first switch 406 may have a second terminal coupled to a second outer conductive segment of the first set of conductive spirals 404 and a second outer conductive segment of the second set of conductive spirals 406. The first winding may include input ports 410 coupled to the first set of conductive spirals 404, for example, at inner conductive segments of the first set of conductive spirals 404. In certain cases, the input ports 410 may be coupled to innermost conductive segments of conductive segments of the first set of conductive spirals 404. The innermost conductive segment of a set of conductive spirals may refer to the conductive segment (or spiral) which is arranged farthest inward with respect to an outermost segment (or spiral) of the set of conductive spirals, for example, as illustrated in FIG. 4B. The outermost conductive segment of a set of conductive spirals may refer to the conductive segment (or spiral) which is arranged farthest outward with respect to an innermost segment (or spiral) of the set of conductive spirals, for example, as illustrated in FIG. 4B. As such, the terms innermost and outermost may be relative to one another.

The first set of conductive spirals 404 may form a first area 412 arranged inside the first set of conductive spirals 404. The second set of conductive spirals 406 may form a second area 414 arranged inside the second set of conductive spirals 406. The first area 412 may be non-overlapping in space with the second area 414. Note that the first area 412 and the second area 414 are depicted smaller than the respective set of conductive spirals 404, 406 to facilitate an understanding of the spatial arrangement of the first set of conductive spirals 404 with respect to the second set of conductive spirals 406. In certain cases, the first area 412 may coincide in space with the first set of conductive spirals 404, and likewise, for the second area 414 with respect to the second set of conductive spirals 406.

Such a spatial arrangement between the first set of conductive spirals 404 and the second set of conductive spirals 406 may allow the second set of conductive spirals to be electrically isolated (e.g., in terms of capacitive coupling and/or inductive coupling) from the first set of conductive spirals 404, for example, when the second set of conductive spirals 406 is inactive or disabled. The electrical isolation between the first set of conductive spirals 404 and the second set of conductive spirals 406 may enable reliable performance across a wide bandwidth of frequencies, for example, including 2.4 GHz to 7.2 GHz. For example, the electrical isolation between the first set of conductive spirals 404 and the second set of conductive spirals 406 may enable a relatively high quality factor (such as 4.5-5.0) across a range of carrier frequencies, for example, including 2.4 GHz to 7.2 GHz.

The first set of conductive spirals 404 may be co-planar with the second set of conductive spirals 406, for example, as depicted in FIGS. 4B and 4C. For example, the first set of conductive spirals 404 may comprise at least one first conductive segment 416 arranged in the layer 402, and the second set of conductive spirals 406 may comprise at least one second conductive segment 418 arranged in the layer. The layer 402 may be a metal layer of an integrated circuit, chip, package, or the like. A metal layer may be or include a layer where one or more conductive traces are formed an integrated circuit, chip, package, or the like.

The RF transformer 400 may include a second conductive winding (hereinafter “the second winding”) configured to be inductively coupled to at least a portion of the first winding. The second winding may be a secondary winding of the RF transformer. The second winding may include a third set of conductive spirals 420 and a fourth set of conductive spirals 422. The second winding may have output ports 426 coupled to the third set of conductive spirals 420, for example, at inner (e.g., innermost) conductive segments of the third set of conductive spirals 420. In certain cases, the output ports 426 may be coupled to the innermost conductive segments of the third set of conductive spirals 420. The fourth set of conductive spirals 422 may be selectively coupled to the third set of conductive spirals 420, for example, via a second switch 424. The second switch 424 may be coupled between the third set of conductive spirals 420 and the fourth set of conductive spirals 422. For example, the second switch 424 may be coupled between outer (e.g., outermost) conductive segments of the third set of conductive spirals 420 and outer (e.g., outermost) conductive segments of the fourth set of conductive spirals 422 (for example, as described herein with respect to the first switch 406).

Each of the first switch 408 and the second switch 424 may be or include one or more transistors. Note that any of the switches described herein may be or include one or more transistors. Note that the first switch 408 and the second switch 424 are illustrated as conceptual representations of switches that enable selective coupling between conductive spirals (and corresponding state of the switch) rather than depicting an example physical arrangement of the switches in the co-planar transformer architecture with respect to the layer 402. Accordingly, aspects of the present disclosure may apply to inductive component architectures that arrange the switches in the same or a different layer as the conductive spirals.

The conductive spirals of the first winding and/or the second winding may be or include electrically conductive material including, for example, various metals, metal alloys, or conductive ceramics. As an example, the conductive spirals of the first winding and/or the second winding may include aluminum (Al), chromium (Cr), cobalt (Co), copper (Cu), tantalum (Ta), titanium (Ti), tungsten (W), and/or the like. Note that any of the conductive windings or spirals may include an electrically conductive material, as described herein.

The third set of conductive spirals 420 may form a third area 428 arranged inside the third set of conductive spirals 420. The third area 428 may overlap in space with the first area 412. The fourth set of conductive spirals 422 may form a fourth area 430 arranged inside the fourth set of conductive spirals 422. The third area 428 may be non-overlapping in space with the fourth area 430, and the fourth area 430 may overlap in space with the second area 414.

Such a spatial arrangement between the third set of conductive spirals 420 and the fourth set of conductive spirals 422 may allow the fourth set of conductive spirals 422 to be electrically isolated from the third set of conductive spirals 420, for example, when the fourth set of conductive spirals 422 is inactive or disabled. The electrical isolation may enable reliable performance across a range of carrier frequencies, for example, as described herein with respect to the first set of conductive spirals 404 and the second set of conductive spirals 406.

The second winding may be co-planar with the first winding, for example, as depicted in FIGS. 4B and 4C. For example, the third set of conductive spirals 420 may have at least one third conductive segment 432 arranged adjacent to the at least one first conductive segment 416 in the layer 402. The fourth set of conductive spirals 422 may have at least one fourth conductive segment 434 arranged adjacent to the at least one second conductive segment 418 in the layer 402.

Each of the first set of conductive spirals 404, the second set of conductive spirals 406, the third set of conductive spirals 420, and the fourth set of conductive spirals 422 may be formed as a symmetric inductor. A symmetric inductor may refer to an inductor spiral that includes loop crossover(s) 436 that symmetrically couple a first portion of an inner loop to a first portion of an outer loop and couple a second portion of the inner loop to a second portion of the outer loop. The symmetric inductor may enable reduced chip area, reduced internal capacitances, and increased quality factor.

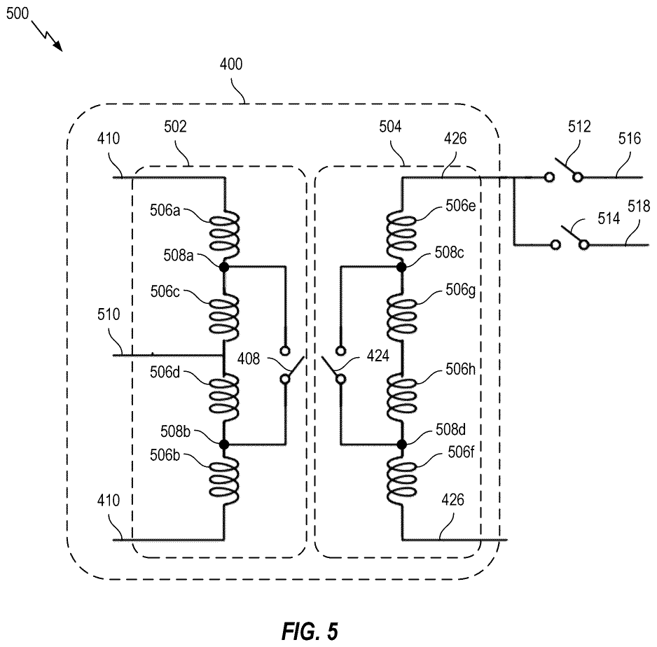

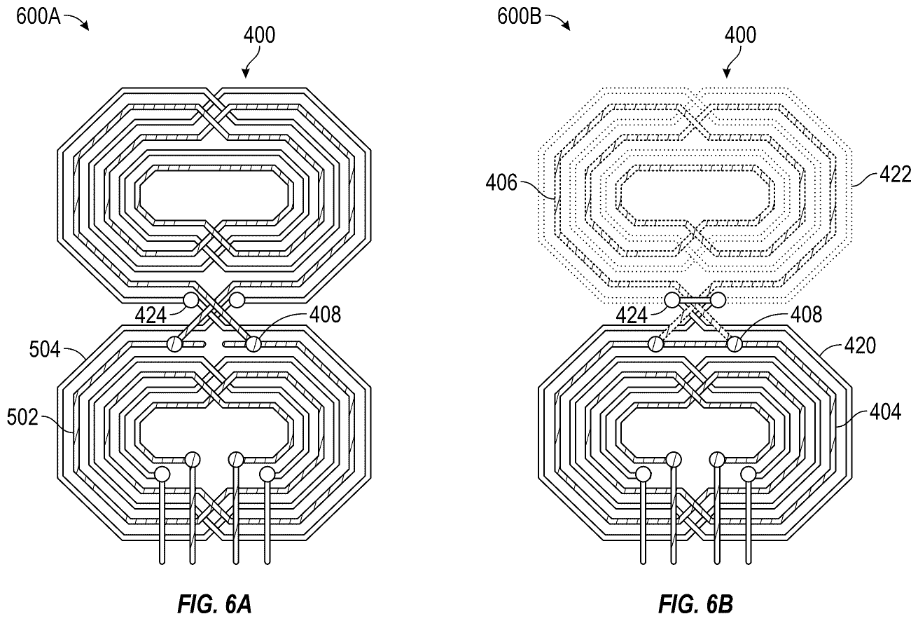

The RF transformer 400 may be configured to operate in a first mode at a first frequency band, for example, one or more 2.4 GHz band(s), as further described herein with respect to FIG. 6A. In the first mode, the second set of conductive spirals 406 may be coupled in series between a first portion of the first set of conductive spirals 404 and a second portion of the first set of conductive spirals 404, for example, as further described herein with respect to FIG. 5. In the first mode, the fourth set of conductive spirals 422 may be coupled in series between a first portion of the third set of conductive spirals 420 and a second portion of the third set of conductive spirals 420, for example, as further described herein with respect to FIG. 5. For example, the first switch 408 and the second switch 424 may be open to conductively couple the first set of conductive spirals 404 to the second set of conductive spirals 406 and to conductively couple the third set of conductive spirals 420 to the fourth set of conductive spirals 422.

The RF transformer 400 may be configured to operate in a second mode at a second frequency band, for example, 5 GHz-7.2 GHz, as further described herein with respect to FIG. 6B. In the second mode, the first set of conductive spirals 404 may be inductively coupled to the third set of conductive spirals 420, and the second set of conductive spirals 406 and the fourth set of conductive spirals 422 may be inactive or disabled. For example, the first switch 408 and the second switch 424 may be open to form an open circuit between the first set of conductive spirals 404 and the second set of conductive spirals 406 and between the third set of conductive spirals 420 and the fourth set of conductive spirals 422.

FIG. 5 depicts an example schematic 500 of the RF transformer 400 of FIG. 4A. In this example, the first set of conductive spirals 404 of the first winding 502 may form a first inductor 506a and a second inductor 506b, and the second set of conductive spirals 406 of the first winding 502 may form a third inductor 506c and a fourth inductor 506d. Each of the inductors 506a-d may be formed via a different portion of the first set of conductive spirals 404 and the second set of conductive spirals 406, respectively. The third inductor 506c may be coupled between the first inductor 506a and the fourth inductor 506d, and the fourth inductor 506d may be coupled between the third inductor 506c and the second inductor 506b. The first switch 408 may be coupled between a first node 508a and a second node 508b. The first node 508a may be coupled between the first inductor 506a and the third inductor 506c, and the second node 508b may be coupled between the second inductor 506b and the fourth inductor 506d. In certain cases, a center tap 510 of the first winding 502 may be coupled between the third inductor 506c and the fourth inductor 506d.

The third set of conductive spirals 420 of the second winding 504 may form a fifth inductor 506e and a sixth inductor 506f, and the fourth set of conductive spirals 422 of the second winding 504 may form a seventh inductor 506g and an eighth inductor 506h. The seventh inductor 506g may be coupled between the fifth inductor 506e and the eighth inductor 506h, and the eighth inductor 506h may be coupled between the seventh inductor 506g and the sixth inductor 506f. The second switch 424 may be coupled between a third node 508c and a fourth node 508d. The third node 508c may be coupled between the fifth inductor 506e and the seventh inductor 506g, and the fourth node 508d may be coupled between the sixth inductor 506f and the eighth inductor 506h.

In certain cases, at least one of the output ports 426 may be coupled to a third switch 512 and a fourth switch 514 to selectively feed the output of the RF transformer 400 to certain output stages of a transmit chain. An output stage may include, for example, one or more amplifiers coupled to one or more antennas. For example, the third switch 512 may enable selective coupling between the RF transformer 400 and a first output stage 516 tuned to operate in a first frequency band (e.g., 2.4 GHz band(s)). The fourth switch 514 may enable selective coupling between the RF transformer 400 and a second output stage 518 tuned to operate in a second frequency band (e.g., 5.0 GHz to 7.2 GHz).

FIG. 6A depicts an example state of the RF transformer 400 of FIG. 4A configured to operate in a first frequency band mode (e.g., 2.4 GHz band(s)). In this example, the first switch 408 and the second switch 424 are open to allow electric current to flow through the conductive spirals of the first winding 502 and the second winding 504.

FIG. 6B depicts an example state of the RF transformer 400 of FIG. 4 configured to operate in a second frequency band mode (e.g., 5.0 GHz to 7.2 GHz). In this example, the first switch 408 and the second switch 424 are closed to allow electric current to bypass the second set of conductive spirals 406 and the fourth set of conductive spirals 422. Thus, electric current flows through the first set of conductive spirals 404 and the third set of conductive spirals 420 of the first winding and the second winding, respectively. The second set of conductive spirals 406 and the fourth set of conductive spirals 422 are illustrated with dashed lines to indicate that these conductive spirals are inactive or disabled.

### Example Wideband Inductive Component With Separated Secondary Windings

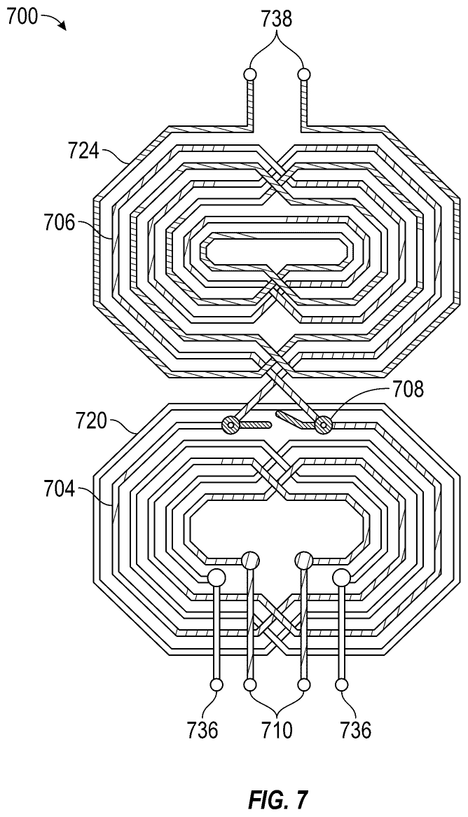

FIG. 7 depicts another example wideband RF transformer (hereinafter the “RF transformer 700”). In this example, the RF transformer 700 may be or include a planar transformer formed at, in, or on a metal layer of an integrated circuit, chip, package, or the like, for example, as described herein with respect to FIG. 4A. In certain aspects, the RF transformer 700 may be an example of a balun. The RF transformer 700 may be included in an RF transceiver, such as the RF transceiver 250 of FIG. 2 and/or a transmit chain, such as the transmit chain 300 of FIG. 3. The RF transformer 700 may be an example of the wideband inductive component 106 of FIGS. 1 and 2.

The RF transformer 700 may include a first conductive winding (hereinafter “the first winding”). The first winding may be formed as described herein with respect to the first winding of FIG. 4A. For example, the first winding may include a first set of conductive spirals 704 and a second set of conductive spirals 706. The second set of conductive spirals 706 may be selectively coupled to the first set of conductive spirals 704 via a switch 708. For example, the switch 708 may be coupled between outer (e.g., outermost) conductive segments of the first set of conductive spirals 704 and outer (e.g., outermost) conductive segments of the second set of conductive spirals 706 (for example, as described herein with respect to the first switch 406 of FIG. 4A). As described above with respect to FIG. 4A, the switch 708 may be depicted as a conceptual representation of the selective coupling between the conductive spirals, such that the switch 708 may be arranged in the same or different layer as the conductive spirals. The first winding may include input ports 710 coupled to the first set of conductive spirals 704, for example, at inner (e.g., innermost) conductive segments of the first set of conductive spirals 704.

The first set of conductive spirals 704 may be arranged to be non-overlapping in space with the second set of conductive spirals 706, for example, as described herein with respect to FIG. 4A. The spatial arrangement of the first set of conductive spirals 704 and the second set of conductive spirals 706 may enable electrical isolation between the first set of conductive spirals 704 and the second set of conductive spirals 706, for example, as described herein with respect to FIG. 4A. The electrical isolation may enable reliable performance across a range of carrier frequencies, for example, as described herein with respect to FIG. 4A.

The RF transformer 700 may include a second conductive winding (hereinafter “the second winding”) configured to be inductively coupled to at least a portion of the first winding. The second winding may be a secondary winding of the RF transformer. The second winding may include a third set of conductive spirals 720 configured or arranged to be inductively coupled to the first set of conductive spirals 704. The second winding may have a first set of output ports 736 coupled to the third set of conductive spirals 720, for example, at inner (e.g., innermost) conductive segments of the third set of conductive spirals 720.

The RF transformer 700 may include a third conductive winding (hereinafter “the third winding”). The third winding may be another secondary winding of the RF transformer. The third winding may include a fourth set of conductive spirals 724 configured or arranged to be inductively coupled to the second set of conductive spirals 706. The third winding may have a second set of output ports 738 coupled to the fourth set of conductive spirals 724, for example, at outer conductive segments of the fourth set of conductive spirals 724.

The third winding may be arranged to be non-overlapping in space with the second winding, for example, as described herein with respect to the third set of conductive spirals 420 and the fourth set of conductive spirals 422 of FIG. 4A. The spatial arrangement of the second winding and the third winding may enable electrical isolation between the second winding and the third winding. Accordingly, the electrical isolation may enable reliable performance across a range of carrier frequencies, for example, as described herein with respect to FIG. 4A.

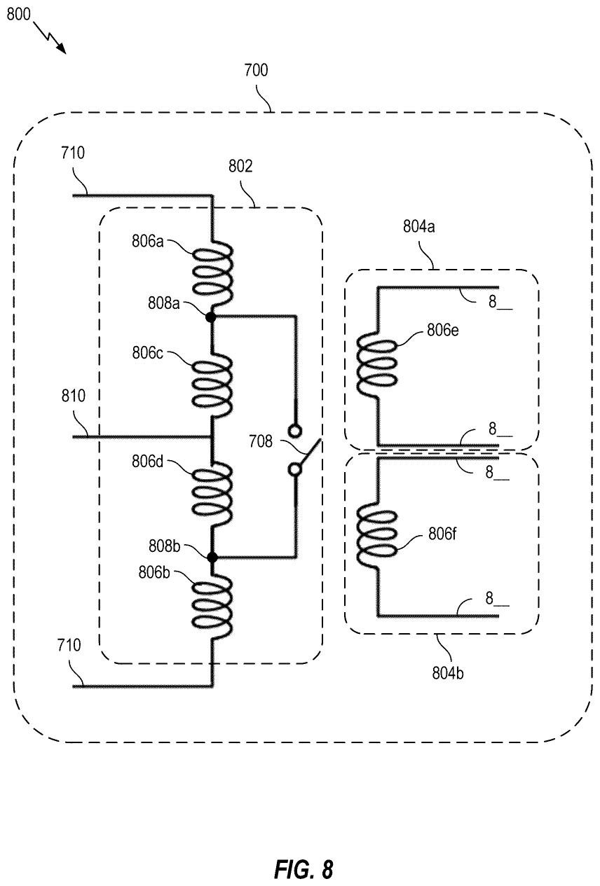

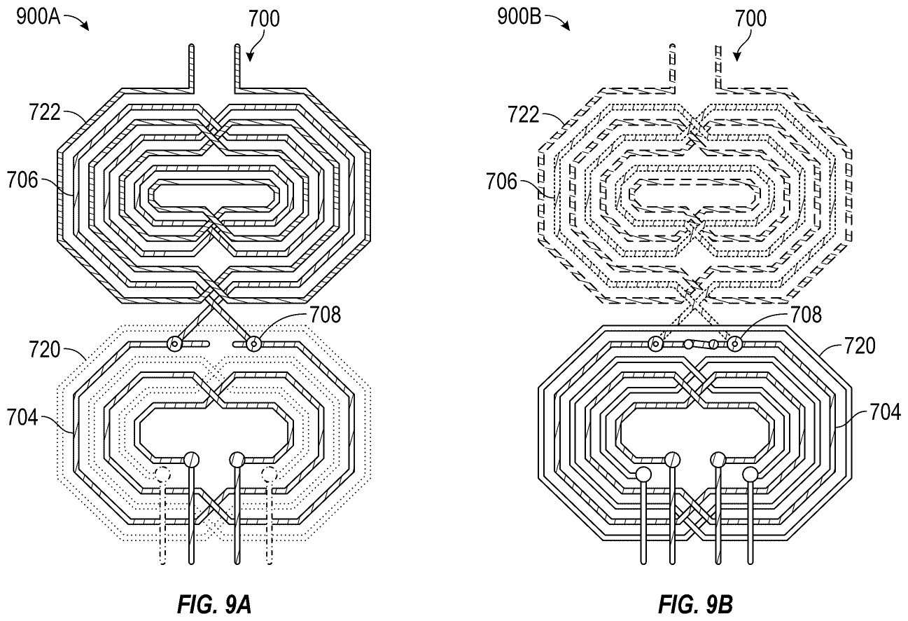

The RF transformer 700 may be configured to operate in a first mode at a first frequency band, for example, one or more 2.4 GHz band(s), as further described herein with respect to FIG. 9A. In the first mode, the second set of conductive spirals 706 may be coupled in series between a first portion of the first set of conductive spirals 704 and a second portion of the first set of conductive spirals 704 (for example, as further described herein with respect to FIG. 8), and the third winding may be inductively coupled to at least the second set of conductive spirals 706. For example, the first switch may be open to allow the first set of conductive spirals 704 to be conductively coupled to the second set of conductive spirals 706. Accordingly, the first winding and the third winding may be tuned to operate at the first frequency band.

The RF transformer 700 may be configured to operate in a second mode at a second frequency band, for example, 5 GHz-7.2 GHz, as further described herein with respect to FIG. 9B. In the second mode, the first set of conductive spirals 704 may be inductively coupled to the second winding (e.g., the third set of conductive spirals 720). For example, the switch 708 may be closed to allow electric current to bypass the second set of conductive spirals 706, and thus, the first set of conductive spirals 704 may be inductively coupled to the second winding (e.g., the third set of conductive spirals 720).

FIG. 8 depicts an example schematic 800 of the RF transformer 700 of FIG. 7. In this example, the first winding 802 of the RF transformer 700 may form a first inductor 806a, a second inductor 806b, a third inductor 806c, and a fourth inductor 806d as described herein with respect to FIG. 5. The switch 708 may be coupled between a first node 808a and a second node 808b as described herein with respect to FIG. 5. The second winding 804a of the RF transformer 700 may form a fifth inductor 806e, and the third winding 804b of the RF transformer 700 may form a sixth inductor 806f. As shown, the second winding 804a and the third winding 804b may be separate circuits enabling electrical isolation when either of the second winding 804a or the third winding 804b is inactive or disabled. The fifth inductor 806e may be configured to operate in the second frequency band (as described herein with respect to FIG. 7), and the sixth inductor 806f may be configured to operate in the first frequency band (as described herein with respect to FIG. 7). In certain cases, a center tap 810 of the first winding 802 may be coupled between the third inductor 806c and the fourth inductor 806d.

FIG. 9A depicts an example state 900A of the RF transformer 700 of FIG. 7 configured to operate in a first frequency band mode (2.4 GHz band(s)). In this example, the switch 708 is open to allow electric current to flow through the first set of conductive spirals 704 and the second set of conductive spirals 706 of the first winding. The third winding (e.g., the fourth set of conductive spirals 722) is active, and the second winding (e.g., the third set of conductive spirals 720) is inactive or disabled. Accordingly, the first winding may be inductively coupled to the third winding without being inductively coupled to the second winding, for example, as further described herein with respect to FIG. 10. The second winding is illustrated with dashed lines to indicate that this winding is inactive or disabled.

FIG. 9B depicts an example state 900B of the RF transformer 700 of FIG. 7 configured to operate in a second frequency band mode. In this example, the switch 708 is closed to allow electric current to bypass the second set of conductive spirals 706 and flow through the first set of conductive spirals 704 of the first winding. In addition, the third winding (e.g., the fourth set of conductive spirals 722) is disabled or inactive, and the second winding (e.g., the third set of conductive spirals 720) is active. Accordingly, the first set of conductive spirals 704 may be inductively coupled to the second winding (e.g., the third set of conductive spirals 720) without being inductively coupled to the third winding (e.g., the fourth set of conductive spirals 722). The second set of conductive spirals 706 and the third winding (e.g., the fourth set of conductive spirals 722) are illustrated with dashed lines to indicate that these elements are inactive or disabled.

### Example Wideband Inductive Component With Secondary Isolation

FIG. 10 depicts an example schematic of a wideband inductive component 1000 with certain secondary winding isolation features. In this example, the wideband inductive component 1000 may be or include an RF transformer (for example, as described herein with respect to FIGS. 3, 4A, and 7) or a balun. The wideband inductive component 1000 may be included in an RF transceiver, such as the RF transceiver 250 of FIG. 2, and/or a transmit chain, such as the transmit chain 300 of FIG. 3. The wideband inductive component 1000 may be an example of the wideband inductive component 106 of FIGS. 1 and 2.

The wideband inductive component 1000 may include a first conductive winding (hereinafter “the first winding 1002”), a second conductive winding (hereinafter “the second winding 1004”), and a third conductive winding (hereinafter “the third winding 1006”). The first winding 1002 may be a primary winding of an RF transformer or a balun. The first winding 1002 may include a first set of conductive spirals and a second set of conductive spirals, such as the conductive spirals of the first winding described herein with respect to FIG. 4A and/or FIG. 7. The first set of conductive spirals may form a first inductor 1008a and a second inductor 1008b, and the second set of conductive spirals may form a third inductor 1008c and a fourth inductor 1008d. The first set of conductive spirals may be selectively coupled to the second set of conductive spirals, for example, via a set of switches 1010. The first winding 1002 may include input ports 1012 and a center tap 1014, which may be coupled between the third inductor 1008c and the fourth inductor 1008d. Note that the arrangement of the switches in the first winding is merely an example to facilitate an understanding of the selective tuning capabilities of the first winding. In certain aspects, the first winding may apply any of the architectures described herein (such as the symmetric inductor structures and/or switching configuration of FIGS. 4A and 7) and/or any suitable transformer architecture.

The second winding 1004 may be a secondary winding of an RF transformer or a balun. In certain aspects, the second winding may be configured to operate at a first frequency band (e.g., 2.4 GHz band(s) and/or 1.4 GHz-2.7 GHz). The second winding 1004 may include a first terminal 1016a, a second terminal 1016b, and a third set of conductive spirals (for example, as described herein with respect to FIG. 7) coupled between the first terminal 1016a and the second terminal 1016b. The third set of conductive spirals may form a fifth inductor 1008e. The second winding 1004 may be configured to be inductively coupled to at least a first portion of the first winding 1002, for example, as described herein with respect to FIG. 7. As an example, the second winding 1004 may be configured to be inductively coupled to the first set of conductive spirals (e.g., the first portion of the first winding) and the second set of conductive spirals (e.g., a second portion of the first winding). When the second winding 1004 is active (and the third winding 1006 is inactive), the first winding 1002 may be configured, via the set of switches 1010, such that the first inductor 1008a, the second inductor 1008b, the third inductor 1008c, and the fourth inductor 1008d of the first winding 1002 are coupled in series with each other.

The third winding 1006 may be a secondary winding of an RF transformer or a balun. In certain aspects, the third winding 1006 may be configured to operate at a second frequency band (e.g., 5-7.2 GHz). For example, the third winding 1006 may have a different inductance and/or a different number of spirals than the second winding 1004. The third winding 1006 may include a third terminal 1016c, a fourth terminal 1016d, and a fourth set of conductive spirals (for example, as described herein with respect to FIG. 7) coupled between the third terminal 1016c and the fourth terminal 1016d. The fourth set of conductive spirals may form a sixth inductor 1008f. The third winding 1006 may be configured to be inductively coupled to at least the first portion of the first winding 1002, for example, as described herein with respect to FIG. 7. When the third winding 1006 is active (and the second winding 1004 is inactive), the first winding 1002 may be configured, via the set of switches 1010, such that the first inductor 1008a and the second inductor 1008b are coupled in series with each other while bypassing the third inductor 1008c and the fourth inductor 1008d.

Each of the second winding 1004 and the third winding 1006 may be selectively coupled to a reference node 1018. The reference node 1018 may be or include a ground node. The reference node 1018 may be a circuit ground, for example, a common ground across a circuit, such as a transceiver circuit. As an example, a first switch 1020 may be coupled between the first terminal 1016a of the second winding 1004 and the reference node 1018. A second switch 1022 may be coupled between the third terminal 1016c of the third winding 1006 and the reference node 1018. The first switch 1020 and the second switch 1022 may be included in an RF transceiver, such as the RF transceiver 250 of FIG. 2. As an example, when the second winding 1004 is active (and the third winding 1006 is inactive), the second switch 1022 may be open to form an open circuit between the third winding 1006 and the reference node 1018, and the first switch 1020 may be closed to couple the reference node 1018 to the second winding 1004. When the third winding 1006 is active (and the second winding 1004 is inactive), the first switch 1020 may be open to form an open circuit between the second winding 1004 and the reference node 1018, and the second switch 1022 may be closed to couple the reference node 1018 to the third winding 1006. Accordingly, the first switch 1020 and/or the second switch 1022 may be used to electrically isolate the inactive secondary winding.

The open circuit may prevent or mitigate internal capacitances from the second winding 1004 or the third winding 1006 from being reflected to the first winding 1002. Accordingly, the open circuit may enable electrical isolation between the first winding 1002 and the second winding 1004, between the first winding 1002 and the third winding 1006, and/or between the second winding 1004 and the third winding 1006, depending on which switch (1020, 1022) is open or closed.

The wideband inductive component 1000 may be configured to operate at a first frequency band (e.g., 2.4 GHz band(s) or 1.4 GHz-2.7 GHz) in a first mode and at a second frequency band (e.g., 5 GHz-7.2 GHz) in a second mode, for example, as described herein with respect to FIGS. 7, 9A, and 9B. As an example, in the first mode, the first switch 1020 may be closed and the second switch 1022 may be open. In the second mode, the first switch 1020 may be open and the second switch 1022 may be closed.

In certain aspects, the second winding 1004 and the third winding 1006 may be coupled to separate switch circuitry. As an example, the switch circuitry may enable selection of a specific output stage to which the wideband inductive component 1000 feeds an RF signal. The separate switch circuitry may enable reduced internal capacitances encountered for a specific winding (such as the second winding or the third winding). As an example, first switch circuitry 1024 may be coupled to the second terminal 1016b of the second winding 1004, and second switch circuitry 1026 may be coupled to the fourth terminal 1016d of the third winding 1006. The first switch circuitry 1024 may include one or more switches coupled in parallel with each other. The second switch circuitry 1026 may include one or more switches coupled in parallel with each other. The second winding 1004 may encounter the internal capacitances of the first switch circuitry 1026 without encountering the internal capacitances of the second switch circuitry 1026, and the third winding 1006 may encounter the internal capacitances of the second switch circuitry 1026 without encountering the internal capacitances of the first switch circuitry 1024. Accordingly, the arrangement of the switch circuitry 1024, 1026 being coupled to separate secondary windings may enabled reduced internal capacitances encountered at the respective secondary winding.

The first switch circuitry 1024 and the second switch circuitry 1026 may enable selective coupling to certain output stages of an RF transceiver, for example, as described herein with respect to FIG. 5. As an example, the second winding 1004 may be selectively coupled to a first set of antennas (such as one of the antennas 220 of FIG. 2) via the first switch circuitry 1024. The third winding 1006 may be selectively coupled to a second set of antennas (such as another one of the antennas 220 of FIG. 2) via the second switch circuitry 1026. In certain cases, the wideband inductive component 1000 may be coupled between one or more amplifiers (such as the PA 230) and the antennas, for example, as described herein with respect to FIG. 2. As example, the wideband inductive component 1000 may be coupled to an output of the amplifier(s).

### Example Operations

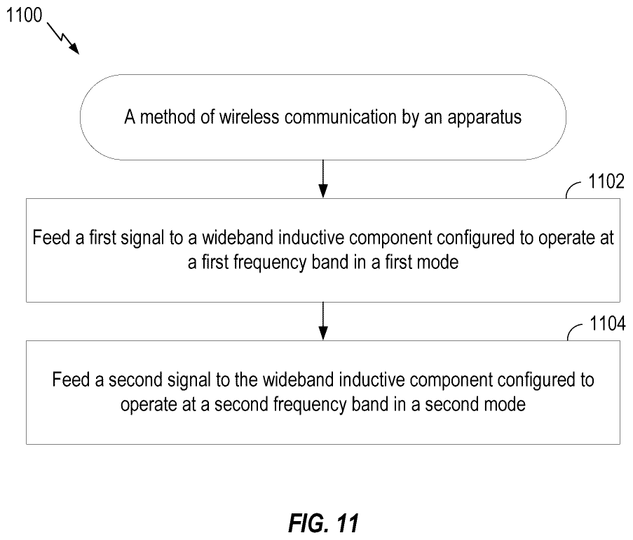

FIG. 11 depicts example operations 1100 for wireless communication. The operations 1100 may be performed, for example, by a wireless device (e.g., the first wireless device 102 in the wireless communications system 100) and/or a transceiver (e.g., the RF transceiver 250). The operations 1100 may be implemented as software components that are executed and run on one or more processors (e.g., the modem 210 and/or the processor 212 of FIG. 2). Further, the transmission and/or reception of signals by the wireless device in the operations 1100 may be enabled, for example, by one or more antennas (e.g., the antenna 220 of FIG. 2). In certain aspects, the transmission and/or reception of signals by the wireless device may be implemented via a bus interface of one or more processors (e.g., the modem 210 and/or the processor 212 of FIG. 2) obtaining and/or outputting signals for reception or transmission.

The operations 1100 may optionally begin, at block 1102, where the wireless device may feed a first signal to a wideband inductive component configured to operate at a first frequency band in a first mode. The wideband inductive component may be any of the wideband inductive components described herein with respect to FIGS. 3-10. As an example, the wideband inductive component may be or include the RF transformer 400, 700 of FIG. 4A and FIG. 7, respectively. In certain aspects, the wideband inductive component may be or include the wideband inductive component of FIG. 10. The wideband inductive component may operate in the first mode as described herein with respect to FIGS. 4A-10.

At block 1104, the wireless device may feed a second signal to the wideband inductive component configured to operate at a second frequency band in a second mode. The wideband inductive component may operate in the second mode as described herein with respect to FIGS. 4A-10.

### Example Aspects

Implementation examples are described in the following numbered clauses:
Aspect 1: A radio frequency (RF) transceiver, comprising: a planar transformer comprising: a first conductive winding comprising a first set of conductive spirals and a second set of conductive spirals selectively coupled to the first set of conductive spirals, wherein the first set of conductive spirals forms a first area inside the first set of conductive spirals, wherein the second set of conductive spirals forms a second area inside the second set of conductive spirals, wherein the first area is non-overlapping in space with the second area, wherein the first set of conductive spirals comprises at least one first conductive segment arranged in a layer, and wherein the second set of conductive spirals comprises at least one second conductive segment arranged in the layer; and a second conductive winding configured to be inductively coupled to at least a portion of the first conductive winding, wherein the second conductive winding comprises a third set of conductive spirals having at least one third conductive segment being arranged adjacent to the at least one first conductive segment in the layer.
Aspect 2: The RF transceiver of Aspect 1, wherein: the third set of conductive spirals forms a third area inside the third set of conductive spirals; and the third area overlaps in space with the first area.
Aspect 3: The RF transceiver of Aspect 2, wherein: the second conductive winding comprises a fourth set of conductive spirals having at least one fourth conductive segment being arranged adjacent to the at least one second conductive segment in the layer; and the fourth set of conductive spirals is selectively coupled to the third set of conductive spirals.
Aspect 4: The RF transceiver of Aspect 3, wherein: the fourth set of conductive spirals forms a fourth area inside the fourth set of conductive spirals; the third area is non-overlapping in space with the fourth area; and the fourth area overlaps in space with the second area.
Aspect 5: The RF transceiver of Aspect 3 or 4, wherein the planar transformer is configured to: operate in a first mode at a first frequency band with the second set of conductive spirals coupled in series between a first portion of the first set of conductive spirals and a second portion of the first set of conductive spirals and with the fourth set of conductive spirals coupled in series between a first portion of the third set of conductive spirals and a second portion of the third set of conductive spirals; and operate in a second mode at a second frequency band with the first set of conductive spirals inductively coupled to the third set of conductive spirals.
Aspect 6: The RF transceiver according to any of Aspects 3-5, wherein the planar transformer further comprises: at least one input port coupled to at least one inner conductive segment of the first set of conductive spirals; at least one output port coupled to at least one inner conductive segment of the third set of conductive spirals; a first switch coupled between at least one outer conductive segment of the first set of conductive spirals and at least one outer conductive segment of the second set of conductive spirals; and a second switch coupled between at least one outer conductive segment of the third set of conductive spirals and at least one outer conductive segment of the fourth set of conductive spirals.
Aspect 7: The RF transceiver according to any of Aspects 2-6, wherein: the planar transformer further comprises a third conductive winding configured to be inductively coupled to the second set of conductive spirals, wherein the third conductive winding comprises a fourth set of conductive spirals having at least one fourth conductive segment being arranged adjacent to the at least one second conductive segment in the layer; and the second conductive winding is configured to be inductively coupled to the first set of conductive spirals.
Aspect 8: The RF transceiver of Aspect 7, wherein: the fourth set of conductive spirals forms a fourth area inside the fourth set of conductive spirals; the third area is non-overlapping in space with the fourth area; and the fourth area overlaps in space with the second area.
Aspect 9: The RF transceiver of Aspect 7 or 8, wherein the planar transformer is configured to: operate in a first mode at a first frequency band with the second set of conductive spirals coupled in series between a first portion of the first set of conductive spirals and a second portion of the first set of conductive spirals and with third conductive winding inductively coupled to the second set of conductive spirals; and operate in a second mode at a second frequency band with the first set of conductive spirals inductively coupled to the second conductive winding.
Aspect 10: The RF transceiver according to any of Aspects 7-9, wherein the planar transformer further comprises a first switch coupled between the first set of conductive spirals and the second set of conductive spirals.
Aspect 11: The RF transceiver according to any of Aspects 1-10, wherein: the layer includes a metal layer of an integrated circuit; and each of the first set of conductive spirals, the second set of conductive spirals, and the third set of conductive spirals are formed in the metal layer.
Aspect 12: The RF transceiver according to any of Aspects 1-11, wherein each of the first set of conductive spirals, the second set of conductive spirals, and the third set of conductive spirals form a respective symmetric inductor spiral.
Aspect 13: The RF transceiver according to any of Aspects 1-12, further comprising a transmit chain comprising the planar transformer.
Aspect 14: The RF transceiver of Aspect 13, wherein the transmit chain further comprises: one or more mixers; and one or more amplifiers, wherein the planar transformer is coupled between the one or more mixers and the one or more amplifiers.
Aspect 15: A radio frequency (RF) transceiver, comprising: a balun comprising: a first conductive winding comprising a first set of conductive spirals and a second set of conductive spirals selectively coupled to the first set of conductive spirals; a second conductive winding selectively coupled to a reference node, wherein the second conductive winding is configured to be inductively coupled to at least a first portion of the first conductive winding; and a third conductive winding selectively coupled to the reference node, wherein the third conductive winding is configured to be inductively coupled to at least the first portion of the first conductive winding.
Aspect 16: The RF transceiver of Aspect 15, further comprising: a first switch, wherein the second conductive winding comprises a first terminal, a second terminal, and a third set of conductive spirals coupled between the first terminal and the second terminal, wherein the first switch is coupled between the first terminal and the reference node.
Aspect 17: The RF transceiver of Aspect 16, further comprising a second switch, wherein the third conductive winding comprises a third terminal, a fourth terminal, and a fourth set of conductive spirals coupled between the third terminal and the fourth terminal, wherein the second switch is coupled between the third terminal and the reference node.
Aspect 18: The RF transceiver of Aspect 17, wherein the balun is configured to: operate at a first frequency band in a first mode where the first switch is closed and the second switch is open; and operate at a second frequency band in a second mode where the first switch is open and the second switch is closed.
Aspect 19: The RF transceiver of Aspect 17 or 18, further comprising a transmit path including the balun and first switch circuitry coupled to the second terminal of the second conductive winding.
Aspect 20: The RF transceiver of Aspect 19, wherein the transmit path further includes one or more amplifiers having an output coupled to the balun.
Aspect 21: The RF transceiver of Aspect 19 or 20, wherein the second conductive winding is selectively coupled to a first set of antennas via the first switch circuitry.
Aspect 22: The RF transceiver according to any of Aspects 19-21, wherein the transmit path further comprises second switch circuitry coupled to the fourth terminal of the third conductive winding.
Aspect 23: The RF transceiver of Aspect 22, wherein the third conductive winding is selectively coupled to a second set of antennas via the second switch circuitry.
Aspect 24: A method of wireless communication by an apparatus, comprising: feed a first signal to a wideband inductive component configured to operate at a first frequency band in a first mode; and feed a second signal to the wideband inductive component configured to operate at a second frequency band in a second mode.
Aspect 25: The method of Aspect 24, wherein the wideband inductive component comprises the planar transformer according to any of Aspects 1-24.
Aspect 26: The method of Aspect 24 or 25, wherein the wideband inductive component comprises the balun according to any of Aspects 15-25.
Aspect 27: An apparatus, comprising: a memory; and one or more processors configured to perform a method in accordance with any of Aspects 24-26.
Aspect 28: An apparatus, comprising means for performing a method in accordance with any of Aspects 24-26.
Aspect 29: A non-transitory computer-readable medium comprising computer-executable instructions that, when executed by one or more processors of a processing system, cause the processing system to perform a method in accordance with any of Aspects 24-26.
Aspect 30: A computer program product embodied on a computer-readable storage medium comprising code for performing a method in accordance with any of Aspects 24-26.
Aspect 31: A method of manufacturing, comprising: forming a radio frequency (RF) transceiver comprising any of Aspects 1-23.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a microcontroller, a microprocessor, a general purpose processor, an artificial intelligence (AI) processor, a digital signal processor (DSP), an ASIC, a field programmable gate array (FPGA) or other programmable logic device (PLD), discrete gate or transistor logic, discrete hardware components, or any combination thereof designed to perform the functions described herein. A general purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), a system in package (SiP), or any other such configuration.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and or like. Also, “determining” may include receiving (e.g., receiving information), accessing (e.g., accessing data in a memory) or the like. Also, “determining” may include resolving, selecting, choosing, establishing or the like.

As used herein, “coupled to” and “coupled with” generally encompass direct coupling and indirect coupling (e.g., including intermediary coupled aspects) unless stated otherwise. For example, stating that a processor is coupled to a memory allows for a direct coupling or a coupling via an intermediary aspect, such as a bus.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Reference to an element in the singular is not intended to mean only one unless specifically so stated, but rather “one or more.” The subsequent use of a definite article (e.g., “the” or “said”) with an element (e.g., “the processor”) is not intended to invoke a singular meaning (e.g., “only one”) on the element unless otherwise specifically stated. For example, reference to an element (e.g., “a processor,” “a controller,” “a memory,” “a transceiver,” “an antenna,” “the processor,” “the controller,” “the memory,” “the transceiver,” “the antenna,” etc.), unless otherwise specifically stated, should be understood to refer to one or more elements (e.g., “one or more processors,” “one or more controllers,” “one or more memories,” “one or more transceivers,” etc.). The terms “set” and “group” are intended to include one or more elements, and may be used interchangeably with “one or more.” Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions. Unless specifically stated otherwise, the term “some” refers to one or more. All structural and functional equivalents to the elements of the various aspects described throughout this disclosure that are known or later come to be known to those of ordinary skill in the art are intended to be encompassed by the claims. Moreover, nothing disclosed herein is intended to be dedicated to the public regardless of whether such disclosure is explicitly recited in the claims.

1. A radio frequency (RF) transceiver, comprising:
a planar transformer comprising:
a first conductive winding comprising a first set of conductive spirals and a second set of conductive spirals selectively coupled to the first set of conductive spirals, wherein the first set of conductive spirals forms a first area inside the first set of conductive spirals, wherein the second set of conductive spirals forms a second area inside the second set of conductive spirals, wherein the first area is non-overlapping in space with the second area, wherein the first set of conductive spirals comprises at least one first conductive segment arranged in a layer, and wherein the second set of conductive spirals comprises at least one second conductive segment arranged in the layer; and
a second conductive winding configured to be inductively coupled to at least a portion of the first conductive winding, wherein the second conductive winding comprises a third set of conductive spirals having at least one third conductive segment being arranged adjacent to the at least one first conductive segment in the layer.

2. The RF transceiver of claim 1, wherein:
the third set of conductive spirals forms a third area inside the third set of conductive spirals; and
the third area overlaps in space with the first area.

3. The RF transceiver of claim 2, wherein:
the second conductive winding comprises a fourth set of conductive spirals having at least one fourth conductive segment being arranged adjacent to the at least one second conductive segment in the layer; and
the fourth set of conductive spirals is selectively coupled to the third set of conductive spirals.

4. The RF transceiver of claim 3, wherein:
the fourth set of conductive spirals forms a fourth area inside the fourth set of conductive spirals;
the third area is non-overlapping in space with the fourth area; and
the fourth area overlaps in space with the second area.

5. The RF transceiver of claim 3, wherein the planar transformer is configured to:
operate in a first mode at a first frequency band with the second set of conductive spirals coupled in series between a first portion of the first set of conductive spirals and a second portion of the first set of conductive spirals and with the fourth set of conductive spirals coupled in series between a first portion of the third set of conductive spirals and a second portion of the third set of conductive spirals; and
operate in a second mode at a second frequency band with the first set of conductive spirals inductively coupled to the third set of conductive spirals.

6. The RF transceiver of claim 3, wherein the planar transformer further comprises:
at least one input port coupled to at least one inner conductive segment of the first set of conductive spirals;
at least one output port coupled to at least one inner conductive segment of the third set of conductive spirals;
a first switch coupled between at least one outer conductive segment of the first set of conductive spirals and at least one outer conductive segment of the second set of conductive spirals; and
a second switch coupled between at least one outer conductive segment of the third set of conductive spirals and at least one outer conductive segment of the fourth set of conductive spirals.

7. The RF transceiver of claim 2, wherein:
the planar transformer further comprises a third conductive winding configured to be inductively coupled to the second set of conductive spirals, wherein the third conductive winding comprises a fourth set of conductive spirals having at least one fourth conductive segment being arranged adjacent to the at least one second conductive segment in the layer; and
the second conductive winding is configured to be inductively coupled to the first set of conductive spirals.

8. The RF transceiver of claim 7, wherein:
the fourth set of conductive spirals forms a fourth area inside the fourth set of conductive spirals;
the third area is non-overlapping in space with the fourth area; and
the fourth area overlaps in space with the second area.

9. The RF transceiver of claim 7, wherein the planar transformer is configured to:
operate in a first mode at a first frequency band with the second set of conductive spirals coupled in series between a first portion of the first set of conductive spirals and a second portion of the first set of conductive spirals and with third conductive winding inductively coupled to the second set of conductive spirals; and
operate in a second mode at a second frequency band with the first set of conductive spirals inductively coupled to the second conductive winding.

10. The RF transceiver of claim 7, wherein the planar transformer further comprises a first switch coupled between the first set of conductive spirals and the second set of conductive spirals.

11. The RF transceiver of claim 1, wherein:
the layer includes a metal layer of an integrated circuit; and
each of the first set of conductive spirals, the second set of conductive spirals, and the third set of conductive spirals are formed in the metal layer.

12. The RF transceiver of claim 1, wherein each of the first set of conductive spirals, the second set of conductive spirals, and the third set of conductive spirals form a respective symmetric inductor spiral.

13. The RF transceiver of claim 1, further comprising a transmit chain comprising the planar transformer.

14. The RF transceiver of claim 13, wherein the transmit chain further comprises:
one or more mixers; and
one or more amplifiers, wherein the planar transformer is coupled between the one or more mixers and the one or more amplifiers.

15. A radio frequency (RF) transceiver, comprising:
a balun comprising:
a first conductive winding comprising a first set of conductive spirals and a second set of conductive spirals selectively coupled to the first set of conductive spirals;
a second conductive winding selectively coupled to a reference node, wherein the second conductive winding is configured to be inductively coupled to at least a first portion of the first conductive winding; and
a third conductive winding selectively coupled to the reference node, wherein the third conductive winding is configured to be inductively coupled to at least the first portion of the first conductive winding.

16. The RF transceiver of claim 15, further comprising: a first switch, wherein the second conductive winding comprises a first terminal, a second terminal, and a third set of conductive spirals coupled between the first terminal and the second terminal, wherein the first switch is coupled between the first terminal and the reference node.

17. The RF transceiver of claim 16, further comprising a second switch, wherein the third conductive winding comprises a third terminal, a fourth terminal, and a fourth set of conductive spirals coupled between the third terminal and the fourth terminal, wherein the second switch is coupled between the third terminal and the reference node.

18. The RF transceiver of claim 17, wherein the balun is configured to:
operate at a first frequency band in a first mode where the first switch is closed and the second switch is open; and
operate at a second frequency band in a second mode where the first switch is open and the second switch is closed.

19. The RF transceiver of claim 17, further comprising a transmit path including the balun and first switch circuitry coupled to the second terminal of the second conductive winding.

20. The RF transceiver of claim 19, wherein the transmit path further comprises second switch circuitry coupled to the fourth terminal of the third conductive winding.
